(19) United States
(12) Patent Application Publication
(10) Pub. No.: US 2026/0342223 A1
(43) Pub. Date: Oct. 29, 2026

(54) CHARGE PUMP DEVICE AND OPERATION METHOD THEREOF AND APPLICATION CIRCUIT

(71) Applicant: Winbond Electronics Corp., Taichung City (TW)

(72) Inventor: Liang-Hsiang Chiu, Hsinchu County (TW)

(73) Assignee: Winbond Electronics Corp., Taichung City (TW)

(21) Appl. No.: 19/467,843

(22) Filed: Feb. 3, 2026

(30) Foreign Application Priority Data
Apr. 25, 2025 (TW) 114115694

(51) Int. Cl. H02M 3/07; G11C 16/30

(52) U.S. Cl. CPC H02M 3/07; G11C 16/30

(57) ABSTRACT

The disclosure provides a charge pump device and an operation method thereof and an application circuit. The charge pump device includes a switch, a charge pump circuit, a slew rate control circuit, and a comparison circuit. The charge pump circuit performs a pumping operation on a power supply voltage based on a clock signal to generate an output voltage. The comparison circuit checks a first reference voltage with a slew rate generated by the slew rate control circuit and a second reference voltage with a fixed level. When the first reference voltage does not reach the second reference voltage, the comparison circuit determines whether to turn on the switch based on the first reference voltage and the output voltage. When the first reference voltage reaches the second reference voltage, the comparison circuit determines whether to turn on the switch based on the second reference voltage and the output voltage.

### CROSS-REFERENCE TO RELATED APPLICATION

This application claims the priority benefit of Taiwan application serial no. 114115694, filed on Apr. 25, 2025. The entirety of the above-mentioned patent application is hereby incorporated by reference herein and made a part of this specification.

### BACKGROUND

### Technical Field

The disclosure relates to a voltage generating circuit, and in particular relates to a charge pump device and an operation method thereof.

### Description of Related Art

Charge pumps are responsible for providing high voltage in various application circuits. For example, in flash memory, charge pumps are responsible for providing high voltage to memory cells for programming, erasing, and reading operations. In application circuits, multiple sets of charge pumps often execute pumping operations on the same power supply voltage (VDD) to generate different high voltages. When multiple charge pumps operate simultaneously, their peak currents may be substantial, causing power drop in the power supply voltage (VDD), which subsequently leads to system interference and malfunction.

### SUMMARY

A charge pump device and an operation method thereof and an application circuit, which execute a pumping operation on a power supply voltage based on the triggering of a clock signal to generate an output voltage, are provided in the disclosure.

In one embodiment, the charge pump device includes a switch, a charge pump circuit, a slew rate control circuit, and a comparison circuit. A first terminal of the switch receives a clock signal. A clock terminal of the charge pump circuit is coupled to a second terminal of the switch. An input terminal of the charge pump circuit receives a power supply voltage. In response to the switch being turned on, the charge pump circuit executes a pumping operation on the power supply voltage based on a clock signal of the clock terminal to generate an output voltage. The slew rate control circuit generates a first reference voltage with a slew rate. The comparison circuit is coupled to the slew rate control circuit to receive the first reference voltage. The comparison circuit is coupled to an output terminal of the charge pump circuit to receive the output voltage. The comparison circuit is coupled to the control terminal of the switch. The comparison circuit checks the first reference voltage and a second reference voltage with a fixed level. In response to the first reference voltage not reaching the second reference voltage, the comparison circuit determines whether to turn on the switch based on a first level relationship between the first reference voltage and the output voltage. In response to the first reference voltage reaching the second reference voltage, the comparison circuit determines whether to turn on the switch based on a second level relationship between the second reference voltage and the output voltage.

In one embodiment, the operation method includes the following operation. A clock signal is received by a first terminal of a switch of a charge pump device. A power supply voltage is received by an input terminal of a charge pump circuit of the charge pump device. A clock terminal of the charge pump circuit is coupled to a second terminal of the switch. A first reference voltage with a slew rate is generated by a slew rate control circuit of the charge pump device. The first reference voltage and a second reference voltage with a fixed level are checked by a comparison circuit of the charge pump device. In response to the first reference voltage not reaching the second reference voltage, the comparison circuit determines whether to turn on the switch based on a first level relationship between the first reference voltage and the output voltage. In response to the first reference voltage reaching the second reference voltage, the comparison circuit determines whether to turn on the switch based on a second level relationship between the second reference voltage and the output voltage. In response to the switch being turned on, the charge pump circuit executes a pumping operation on the power supply voltage based on the clock signal of the clock terminal to generate the output voltage.

In one embodiment, the application circuit includes multiple charge pump devices. Input terminals of the charge pump devices receive a same power supply voltage. The charge pump devices execute a pumping operation on the power supply voltage based on triggering of a clock signal to generate multiple output voltages with dispersed slew rates.

Based on the above, the application circuits described in the embodiments of the disclosure include multiple charge pump devices, and each charge pump device may perform a pumping operation on a power supply voltage based on the triggering of a clock signal to generate an output voltage. The slew rate control circuit generates a first reference voltage with a controllable slew rate. When the first reference voltage does not reach a certain preset fixed voltage (second reference voltage), whether the switch is turned on or off is based on the level relationship between the first reference voltage and the output voltage. When the switch is turned on, the charge pump circuit executes a pumping operation based on the clock signal to generate the output voltage. Therefore, the charge pump device pulls up (or pulls down) the output voltage at a controllable slew rate during the initial power-on stage. When the first reference voltage reaches the second reference voltage, whether the switch is turned on or off is based on the level relationship between the second reference voltage and the output voltage. Therefore, the charge pump device may maintain the output voltage at a target level after the initial power-on stage ends. In an application scenario where an application circuit uses multiple charge pump devices simultaneously, different charge pump devices may be set with different slew rates (so that the slew rates are dispersed) to generate different output voltages with dispersed rising (or falling) rates at the initial power-on stage. Therefore, when multiple charge pump devices are powered on simultaneously, the peak value of the power supply current may be effectively reduced because the different output voltages of the charge pump devices have dispersed slew rates at the initial power-on stage.

### BRIEF DESCRIPTION OF THE DRAWINGS

FIG. 1 is a block diagram of an application circuit according to an embodiment.

FIG. 2 is a schematic diagram showing waveforms of the output voltages and the power supply current of the charge pumps at the initial power-on stage when multiple charge pumps are operated simultaneously.

FIG. 3 is a block diagram of a charge pump device according to an embodiment of the disclosure.

FIG. 4 is a schematic diagram of the flow of an operation method of a charge pump device according to an embodiment of the disclosure.

FIG. 5 is a schematic diagram showing waveforms of an output voltage, a reference voltage, a reference voltage, and a power supply current of a charge pump device at an initial power-on stage according to an embodiment of the disclosure.

FIG. 6 is a block diagram of a comparison circuit according to an embodiment of the disclosure.

FIG. 7 is a block diagram of a slew rate control circuit according to an embodiment of the disclosure.

### DETAILED DESCRIPTION OF DISCLOSED EMBODIMENTS

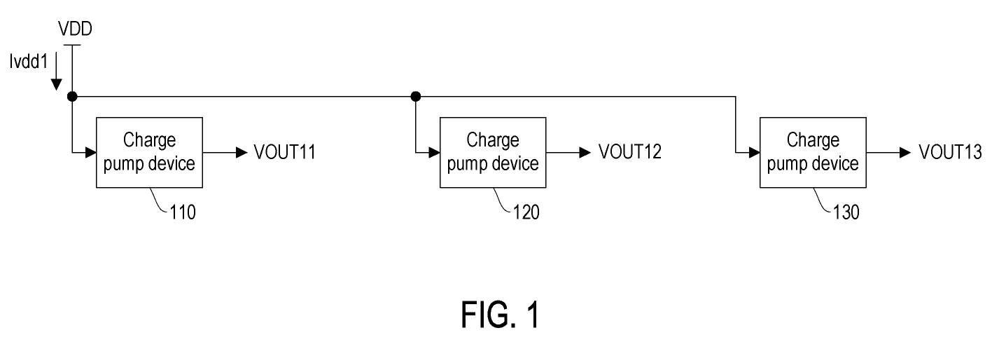

FIG. 1 is a block diagram of an application circuit according to an embodiment. In the example shown in FIG. 1, the application circuit is assumed to have three charge pump devices 110, 120 and 130. Input terminals of the charge pump devices 110, 120 and 130 receive the same power supply voltage VDD. In the application circuit, the charge pump devices 110, 120 and 130 execute a pumping operation on the power supply voltage VDD to generate output voltages VOUT11, VOUT12 and VOUT13 of different levels. When the charge pump devices 110, 120, and 130 are powered on simultaneously, the peak value of the power supply current Ivdd1 will be very large, causing a non-negligible power drop in the power supply voltage VDD.

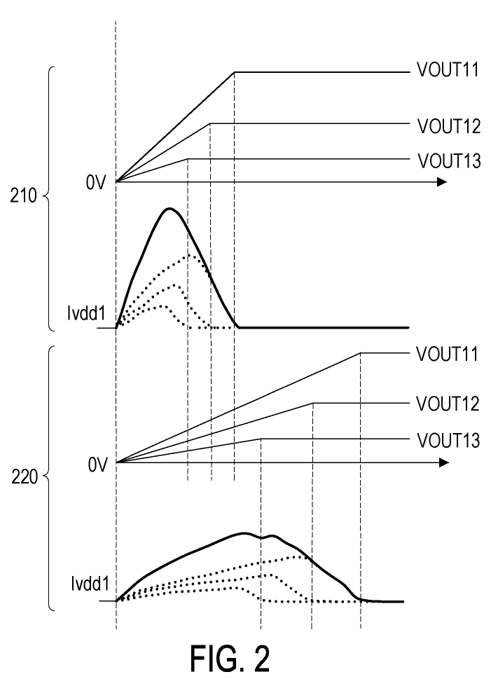

FIG. 2 is a schematic diagram showing waveforms of the output voltages VOUT11, VOUT12, and VOUT13 and the power supply current Ivdd1 of the charge pump devices 110, 120, and 130 at the initial power-on stage when multiple charge pump devices 110, 120, and 130 are operated simultaneously. The horizontal axis of FIG. 2 represents time. The upper portion 210 of FIG. 2 illustrates different output voltages VOUT11, VOUT12, and VOUT13 generated by the charge pump devices 110, 120, and 130 simultaneously executing pumping operations on the power supply voltage VDD after the charge pump devices 110, 120, and 130 are powered on simultaneously. When the charge pump devices 110, 120, and 130 are powered on simultaneously, the charge pump devices 110, 120, and 130 will exert maximum effort to elevate output voltages VOUT11, VOUT12, and VOUT13 to different preset voltage levels. Generally speaking, the rising rates of the output voltages VOUT11, VOUT12, and VOUT13, also known as slew rates, are basically similar to each other. In this case, the charge pump devices 110, 120, and 130 consume a large current at the initial power-on stage. The upper portion 210 of FIG. 2 illustrates the power supply current Ivdd1 shown in FIG. 1. Because the charge pump devices 110, 120 and 130 pull up the output voltages VOUT11, VOUT12 and VOUT13 at similar slew rates, in this case, the peak value of the power supply current Ivdd1 (i.e., the sum of the currents consumed by the charge pump devices 110, 120 and 130) is very large, causing a non-negligible level drop in the power supply voltage VDD, thereby causing system interference and malfunction.

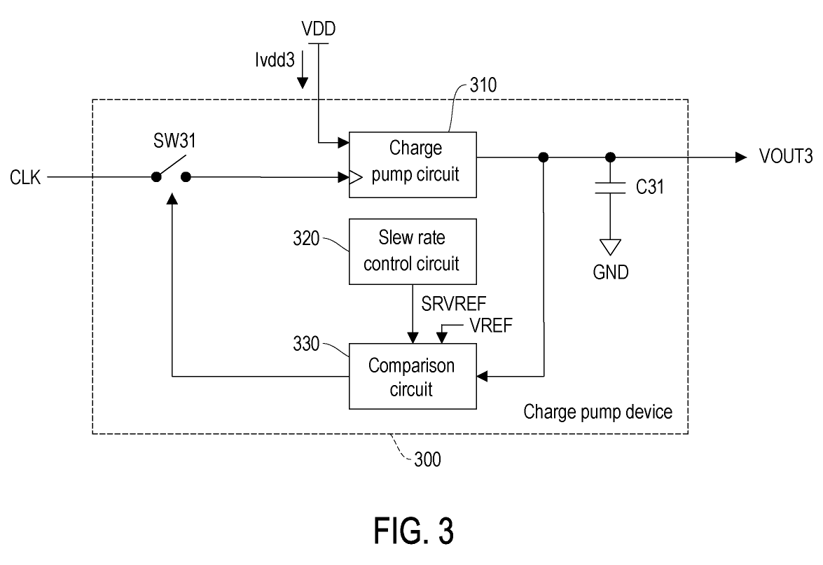

FIG. 3 is a circuit block diagram of a charge pump device 300 according to an embodiment of the disclosure. Referring to FIG. 3, the charge pump device 300 executes a pumping operation on the power supply voltage VDD based on the triggering of a clock signal CLK to generate a pump voltage (output voltage VOUT3). The charge pump device 300 may be applied in various application circuits to provide the output voltage VOUT3. For example (but not limited thereto), the charge pump device 300 may be applied in a flash memory to provide the output voltage VOUT3 to memory cells for programming, erasing, and reading operations. In the embodiment of the disclosure, the charge pump device 300 pulls up (or pulls down) the output voltage VOUT3 at a controllable slew rate at the initial power-on stage. Therefore, in an application scenario where multiple charge pump devices 300 are used simultaneously, different charge pump devices 300 may be set with different slew rates (to disperse the slew rates) to generate different output voltages VOUT3 with different rising (or falling) rates at the initial power-on stage. "Dispersing the slew rates" means increasing the difference between the slew rates of different charge pump devices.

In the embodiment shown in FIG. 3, the charge pump device 300 includes a switch SW31, a charge pump circuit 310, a slew rate control circuit 320, a comparison circuit 330, and an output capacitor C31. This embodiment does not limit the specific implementation of the switch SW31. For example, the switch SW31 may include a switching transistor, a transmission gate, a logic gate, or other switching circuits (or switching elements). Taking the logic gate as an example, the first input terminal of the logic gate serves as the first terminal of the switch SW31, the second input terminal of the logic gate serves as the control terminal of the switch SW31, and the output terminal of the logic gate serves as the second terminal of the switch SW31. According to actual design, the logic gate includes an AND gate, a NAND gate or other logic gates.

The first terminal of the switch SW31 receives the clock signal CLK. A clock terminal of the charge pump circuit 310 is coupled to the second terminal of the switch SW31. An input terminal of the charge pump circuit 310 receives the power supply voltage VDD. A first terminal of the output capacitor C31 is coupled to an output terminal of the charge pump circuit 310. A second terminal of the output capacitor C31 is coupled to a reference voltage (e.g., the ground voltage GND or other fixed voltage). In response to the switch SW31 being turned on, the charge pump circuit 310 executes a pumping operation on the power supply voltage VDD based on the clock signal CLK of the clock terminal to generate the output voltage VOUT3. In response to the switch SW31 being turned off, the charge pump circuit 310 stops executing the pumping operation on the power supply voltage VDD due to the disappearance of the clock signal CLK.

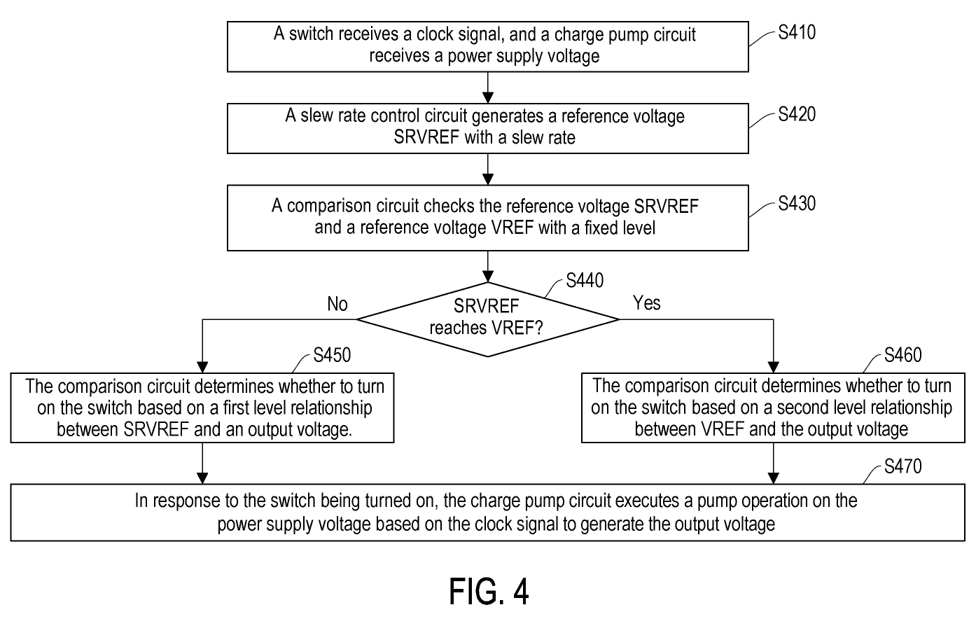

FIG. 4 is a schematic diagram of the flow of an operation method of a charge pump device according to an embodiment of the disclosure. Referring to FIGS. 3 and 4, in step S410, the first terminal of the switch SW31 receives the clock signal CLK, and the input terminal of the charge pump circuit 310 receives the power supply voltage VDD. In step S420, the slew rate control circuit 320 generates a reference voltage SRVREF with a slew rate (in the initial power-on stage, the slew rate of the reference voltage SRVREF is not 0). A first input terminal of the comparison circuit 330 is coupled to the output terminal of the slew rate control circuit 320 to receive the reference voltage SRVREF. A second input terminal of the comparison circuit 330 is coupled to the output terminal of the charge pump circuit 310 to receive the output voltage VOUT3. An output terminal of the comparison circuit 330 is coupled to the control terminal of the switch SW31. In step S430, the comparison circuit 330 checks the reference voltage SRVREF (the first reference voltage) and a reference voltage VREF (the second reference voltage) with a fixed level.

In response to the reference voltage SRVREF not reaching the reference voltage VREF at the initial power-on stage (i.e., SRVREF<VREF, the determination result of step S440 is “No”), the charge pump device 300 proceeds to step S450. In step S450, the comparison circuit 330 determines whether to turn on the switch SW31 based on a first level relationship between the reference voltage SRVREF and the output voltage VOUT3. In response to the reference voltage SRVREF having reached the reference voltage VREF (i.e., SRVREF ≥ VREF, the determination result of step S440 is “yes”), the charge pump device 300 proceeds to step S460. In step S460, the comparison circuit 330 determines whether to turn on the switch SW31 based on a second level relationship between the reference voltage VREF and the output voltage VOUT3.

In step S470, in response to the switch SW31 being turned on, the charge pump circuit 310 executes a pumping operation on the power supply voltage VDD based on the clock signal CLK to generate the output voltage VOUT3. In response to the switch SW31 being turned off, the charge pump circuit 310 stops executing the pumping operation on the power supply voltage VDD due to the disappearance of the clock signal CLK.

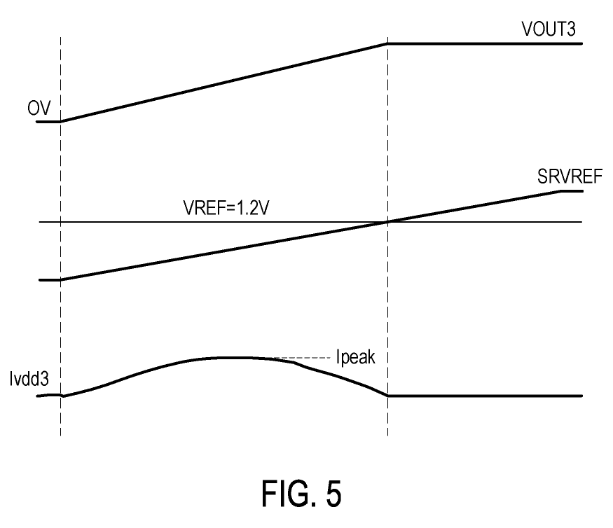

FIG. 5 is a schematic diagram showing waveforms of the output voltage VOUT3, the reference voltage VREF, the reference voltage SRVREF, and the power supply current Ivdd3 of the charge pump device 300 at the initial power-on stage according to an embodiment of the disclosure. The horizontal axis of FIG. 5 represents time. The upper portion of FIG. 5 illustrates the output voltage VOUT3 generated by the charge pump circuit 310 executing a pump operation on the power supply voltage VDD after the charge pump device 300 is powered on. The middle portion of FIG. 5 illustrates the reference voltage VREF and the reference voltage SRVREF after the charge pump device 300 is powered on. The reference voltage SRVREF has a controllable slew rate at the initial power-on stage (described in detail later). The reference voltage VREF has a fixed level (e.g., 1.2V, but not limited thereto). The lower portion of FIG. 5 illustrates the power supply current Ivdd3 shown in FIG. 3.

In response to the reference voltage SRVREF not reaching the reference voltage VREF at the initial power-on stage, the comparison circuit 330 determines whether to turn on the switch SW31 based on a first level relationship between the reference voltage SRVREF and the output voltage VOUT3. Therefore, the output voltage VOUT3 is pulled up based on the controllable slew rate of the reference voltage SRVREF. That is, the slew rate of the output voltage VOUT3 is a controllable slew rate corresponding to the reference voltage SRVREF. In response to the reference voltage SRVREF reaching the reference voltage VREF, the comparison circuit 330 determines whether to turn on the switch SW31 based on a second level relationship between the reference voltage VREF and the output voltage VOUT3. Therefore, the charge pump circuit 310 may maintain the output voltage VOUT3 at a target level after the initial power-on stage ends. That is, the target level of the output voltage VOUT3 corresponds to the level of the reference voltage VREF.

In summary, the charge pump device 300 may generate the output voltage VOUT3 by executing a pumping operation on the power supply voltage VDD based on the triggering of the clock signal CLK. The slew rate control circuit 320 generates a reference voltage SRVREF with a controllable slew rate. When the reference voltage SRVREF does not reach a certain preset fixed voltage (reference voltage VREF), whether the switch SW31 is turned on or off is based on the level relationship between the reference voltage SRVREF and the output voltage VOUT3. When the switch SW31 is turned on, the charge pump circuit 310 executes a pumping operation based on the clock signal CLK to generate the output voltage VOUT3. Therefore, the charge pump device 300 pulls up (or pulls down) the output voltage VOUT3 at a controllable slew rate during the initial power-on stage. Because the output voltage VOUT3 of the charge pump device 300 has a controllable slew rate at the initial power-on stage, the peak value Ipeak of the power supply current Ivdd3 may be effectively reduced. When the reference voltage SRVREF reaches the reference voltage VREF, whether the switch SW31 is turned on or off is based on the level relationship between the reference voltage VREF and the output voltage VOUT3. Therefore, the charge pump device 300 may maintain the output voltage VOUT3 at the target level after the initial power-on stage ends.

In an application scenario where multiple charge pump devices 300 are used simultaneously, different charge pump devices 300 may be set with different slew rates to generate different output voltages VOUT3 with different rising (or falling) rates at the initial power-on stage. Therefore, when multiple charge pump devices 300 are powered on simultaneously, the peak value Ipeak of the power supply current Ivdd3 may be effectively reduced because different output voltages VOUT3 of the charge pump devices 300 have different slew rates at the initial power-on stage.

For example, the charge pump device 300 may serve as one of the many embodiments of the charge pump devices 110, 120, and 130 shown in FIG. 1. In the application scenario where the charge pump device 300 is used to implement each of the charge pump devices 110, 120, and 130 shown in FIG. 1, the charge pump devices 110, 120, and 130 execute a pumping operation on the power supply voltage VDD to generate output voltages VOUT11, VOUT12, and VOUT13 of different levels. The charge pump devices 110, 120, and 130 (multiple charge pump devices 300) may be set with different slew rates. When the charge pump devices 110, 120, and 130 are powered on simultaneously, the charge pump devices 110, 120, and 130 generate different output voltages VOUT11, VOUT12, and VOUT13 with different rising (or falling) rates at the initial power-on stage.

The lower portion 220 of FIG. 2 illustrates an example of implementing each of the charge pump devices 110, 120, and 130 shown in FIG. 1 with the charge pump device 300 shown in FIG. 3. After the charge pump devices 110, 120 and 130 are powered on simultaneously, the charge pump devices 110, 120 and 130 (multiple charge pump devices 300) simultaneously execute a pumping operation on the power supply voltage VDD at different slew rates to generate different output voltages VOUT11, VOUT12 and VOUT13 (different preset voltage levels). That is, the charge pump devices 110, 120, and 130 pull up the output voltages VOUT11, VOUT12, and VOUT13 at different slew rates. The lower portion 220 of FIG. 2 illustrates the power supply current Ivdd1 shown in FIG. 1. Under different slew rates, the peak value of the power supply current Ivdd1 (i.e., the sum of the currents consumed by the charge pump devices 110, 120, and 130) may be effectively reduced.

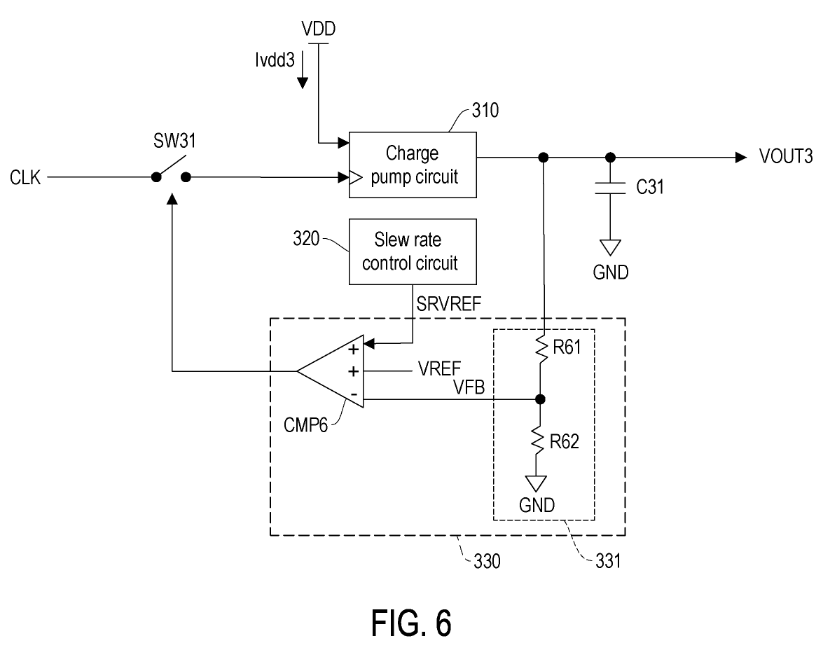

FIG. 6 is a block diagram of a comparison circuit 330 according to an embodiment of the disclosure. In the embodiment of FIG. 6, the comparison circuit 330 includes a feedback circuit 331 and a comparator CMP6. Referring to FIGS. 5 and 6, an input terminal of the feedback circuit 331 is coupled to the output terminal of the charge pump circuit 310 to receive the output voltage VOUT3. The feedback circuit 331 generates a feedback voltage VFB based on the output voltage VOUT3. In the embodiment of FIG. 6, the feedback circuit 331 includes a resistor R61 and a resistor R62. A first terminal of the resistor R61 is coupled to the output terminal of the charge pump circuit 310 to receive the output voltage VOUT3. A second terminal of the resistor R61 is coupled to an inverting input terminal of the comparator CMP6 to provide the feedback voltage VFB. A first terminal of the resistor R62 is coupled to a second terminal of the resistor R61. A second terminal of the resistor R62 is coupled to a reference voltage (e.g., the ground voltage GND or other fixed voltage). This embodiment does not limit the specific implementation of the feedback circuit 331. In other embodiments, the feedback circuit 331 may also directly use the output voltage VOUT3 as the feedback voltage VFB.

A first non-inverting input terminal of the comparator CMP6 is coupled to the slew rate control circuit 320 to receive the reference voltage SRVREF. A second non-inverting input terminal of the comparator CMP6 receives the reference voltage VREF. An inverting input terminal of the comparator CMP6 is coupled to the output terminal of the feedback circuit 331 to receive the feedback voltage VFB. An output terminal of the comparator CMP6 is coupled to the control terminal of the switch SW31. The comparator CMP6 determines whether to turn on the switch SW31 based on the comparison result of the reference voltage SRVREF, the reference voltage VREF, and the feedback voltage VFB. For example, in response to the reference voltage SRVREF not reaching the reference voltage VREF, the comparator CMP6 compares the reference voltage SRVREF and the feedback voltage VFB. In response to the feedback voltage VFB being less than the reference voltage SRVREF, the comparator CMP6 turns on the switch SW31. In response to the feedback voltage VFB being greater than the reference voltage SRVREF, the comparator CMP6 turns off the switch SW31.

In response to the reference voltage SRVREF reaching the reference voltage VREF, the comparator CMP6 compares the reference voltage VREF and the feedback voltage VFB. In response to the feedback voltage VFB being less than the reference voltage VREF, the comparator CMP6 turns on the switch SW31. In response to the feedback voltage VFB being greater than the reference voltage VREF, the comparator CMP6 turns off the switch SW31.

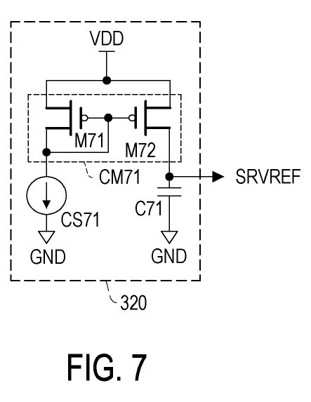

FIG. 7 is a block diagram of a slew rate control circuit 320 according to an embodiment of the disclosure. In the embodiment of FIG. 7, the slew rate control circuit 320 includes a current mirror CM71, a current source CS71, and a capacitor C71. The current mirror CM71 has a main current path and a slave current path, in which a first terminal of the main current path and a first terminal of the slave current path receive the power supply voltage VDD. The current source CS71 is coupled to a second terminal of the main current path of the current mirror CM71. A first terminal of the capacitor C71 is coupled to a second terminal of the slave current path of the current mirror CM71. A second terminal of the capacitor C71 is coupled to a reference voltage (e.g., the ground voltage GND or other fixed voltage). At the initial power-on stage of the power supply voltage VDD, the second terminal of the slave current path of the current mirror CM71 generates the reference voltage SRVREF with a slew rate to the comparison circuit 330.

In the embodiment of FIG. 7, the current mirror CM71 includes a transistor M71 and a transistor M72. The transistor M71 provides the main current path of the current mirror CM71, and the transistor M72 provides the slave current path of the current mirror CM71. A first terminal (e.g., source) of the transistor M71 serves as the first terminal of the main current path. A second terminal (e.g., drain) of the transistor M71 serves as the second terminal of the main current path. A control terminal (e.g., a gate) of the transistor M71 is coupled to the second terminal of the transistor M71. A first terminal (e.g., source) of the transistor M72 serves as the first terminal of the slave current path. A second terminal (e.g., drain) of the transistor M72 serves as the second terminal of the slave current path. A control terminal (e.g., gate) of the transistor M72 is coupled to the control terminal of the transistor M71.

In the embodiment of FIG. 7, the reference voltage SRVREF may provide different slew rates according to design requirements based on the current multiplier of the configured current mirror CM71, or based on the current of the configured current source CS71, or based on the capacitance of the configured capacitor C71. In addition, in order to increase design flexibility, in other embodiments, the transistor M72 may adopt a variable transistor (i.e., the equivalent channel aspect ratio of the transistor M72 is adjustable) to adjust the current multiplier of the current mirror CM71 according to different application scenarios, thereby adjusting the slew rate of the reference voltage SRVREF; alternatively, the capacitor C71 may adopt a variable capacitor (i.e., the equivalent capacitance of the capacitor C71 is adjustable) to adjust the capacitance of the capacitor C71 according to different application scenarios, thereby adjusting the slew rate of the reference voltage SRVREF.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A charge pump device, configured to execute a pumping operation on a power supply voltage based on triggering of a clock signal to generate an output voltage, the charge pump device comprising:
a switch, having a first terminal receiving the clock signal;
a charge pump circuit, having a clock terminal coupled to a second terminal of the switch, wherein an input terminal of the charge pump circuit receives the power supply voltage, and in response to the switch being turned on, the charge pump circuit executes the pumping operation on the power supply voltage based on the clock signal of the clock terminal to generate the output voltage;
a slew rate control circuit, generating a first reference voltage with a slew rate; and
a comparison circuit, coupled to the slew rate control circuit to receive the first reference voltage, coupled to an output terminal of the charge pump circuit to receive the output voltage, and coupled to a control terminal of the switch, wherein the comparison circuit checks the first reference voltage and a second reference voltage with a fixed level, wherein
in response to the first reference voltage not reaching the second reference voltage, the comparison circuit determines whether to turn on the switch based on a first level relationship between the first reference voltage and the output voltage;
in response to the first reference voltage reaching the second reference voltage, the comparison circuit determines whether to turn on the switch based on a second level relationship between the second reference voltage and the output voltage.

2. The charge pump device according to claim 1, wherein the switch comprises:
a logic gate, wherein a first input terminal of the logic gate serves as the first terminal of the switch, a second input terminal of the logic gate serves as the control terminal of the switch, and an output terminal of the logic gate serves as the second terminal of the switch.

3. The charge pump device according to claim 2, wherein the logic gate comprises an AND gate or a NAND gate.

4. The charge pump device according to claim 1, wherein the slew rate control circuit comprises:
a current mirror, having a main current path and a slave current path, wherein a first terminal of the main current path and a first terminal of the slave current path receive the power supply voltage;
a current source, coupled to a second terminal of the main current path; and
a capacitor, coupled to a second terminal of the slave current path,
wherein the second terminal of the slave current path generates the first reference voltage with the slew rate to the comparison circuit in a power-on stage of the power supply voltage.

5. The charge pump device according to claim 4, wherein the capacitor is a variable capacitor.

6. The charge pump device according to claim 4, wherein the current mirror comprises:
a first transistor, providing the main current path, wherein a first terminal of the first transistor serves as the first terminal of the main current path, a second terminal of the first transistor serves as the second terminal of the main current path, and a control terminal of the first transistor is coupled to the second terminal of the first transistor; and
a second transistor, providing the slave current path, wherein a first terminal of the second transistor serves as the first terminal of the slave current path, a second terminal of the second transistor serves as the second terminal of the slave current path, and a control terminal of the second transistor is coupled to the control terminal of the first transistor.

7. The charge pump device according to claim 6, wherein the second transistor is a variable transistor.

8. The charge pump device according to claim 1, wherein the comparison circuit comprises:
a feedback circuit, having an input terminal coupled to the output terminal of the charge pump circuit to receive the output voltage, wherein the feedback circuit generates a feedback voltage based on the output voltage; and
a comparator, determining whether to turn on the switch based on the first reference voltage, the second reference voltage and the feedback voltage, wherein a first non-inverting input terminal of the comparator is coupled to the slew rate control circuit to receive the first reference voltage, a second non-inverting input terminal of the comparator receives the second reference voltage, an inverting input terminal of the comparator is coupled to an output terminal of the feedback circuit to receive the feedback voltage, and an output terminal of the comparator is coupled to the control terminal of the switch.

9. The charge pump device according to claim 8, wherein the feedback circuit comprises:
a first resistor, having a first terminal coupled to the output terminal of the charge pump circuit to receive the output voltage, wherein a second terminal of the first resistor is coupled to the inverting input terminal of the comparator to provide the feedback voltage; and
a second resistor, has a first terminal coupled to the second terminal of the first resistor, wherein a second terminal of the second resistor is coupled to a third reference voltage.

10. The charge pump device according to claim 8, wherein,
in response to the first reference voltage not reaching the second reference voltage, the comparator compares the first reference voltage and the feedback voltage;
in response to the feedback voltage being less than the first reference voltage, the comparator turns on the switch; and
in response to the feedback voltage being greater than the first reference voltage, the comparator turns off the switch.

11. The charge pump device according to claim 8, wherein,
in response to the first reference voltage reaching the second reference voltage, the comparator compares the second reference voltage and the feedback voltage;
in response to the feedback voltage being less than the second reference voltage, the comparator turns on the switch; and
in response to the feedback voltage being greater than the second reference voltage, the comparator turns off the switch.

12. The charge pump device according to claim 1, further comprising:
an output capacitor, coupled to the output terminal of the charge pump circuit.

13. An operation method of a charge pump device, the charge pump device is configured to execute a pump operation on a power supply voltage based on triggering of a clock signal to generate an output voltage, the operation method comprising:
receiving the clock signal by a first terminal of a switch of the charge pump device;
receiving the power supply voltage by an input terminal of a charge pump circuit of the charge pump device, wherein a clock terminal of the charge pump circuit is coupled to a second terminal of the switch;
generating a first reference voltage with a slew rate by a slew rate control circuit of the charge pump device;
checking the first reference voltage and a second reference voltage with a fixed level by a comparison circuit of the charge pump device, wherein the comparison circuit is coupled to the slew rate control circuit to receive the first reference voltage, the comparison circuit is coupled to an output terminal of the charge pump circuit to receive the output voltage, and the comparison circuit is coupled to a control terminal of the switch; wherein
in response to the first reference voltage not reaching the second reference voltage, the comparison circuit determines whether to turn on the switch based on a first level relationship between the first reference voltage and the output voltage;
in response to the first reference voltage reaching the second reference voltage, the comparison circuit determines whether to turn on the switch based on a second level relationship between the second reference voltage and the output voltage; and
in response to the switch being turned on, the charge pump circuit executes the pumping operation on the power supply voltage based on the clock signal of the clock terminal to generate the output voltage.

14. The operation method according to claim 13, further comprising:
generating a feedback voltage based on the output voltage by a feedback circuit of the comparison circuit, wherein an input terminal of the feedback circuit is coupled to the output terminal of the charge pump circuit to receive the output voltage; and
determining whether to turn on the switch based on the first reference voltage, the second reference voltage and the feedback voltage by a comparator of the comparison circuit, wherein a first non-inverting input terminal of the comparator is coupled to the slew rate control circuit to receive the first reference voltage, a second non-inverting input terminal of the comparator receives the second reference voltage, an inverting input terminal of the comparator is coupled to an output terminal of the feedback circuit to receive the feedback voltage, and an output terminal of the comparator is coupled to the control terminal of the switch.

15. The operation method according to claim 14, wherein
in response to the first reference voltage not reaching the second reference voltage, comparing the first reference voltage and the feedback voltage by the comparator;
in response to the feedback voltage being less than the first reference voltage, turning on the switch by the comparator; and
in response to the feedback voltage being greater than the first reference voltage, turning off the switch by the comparator.

16. The operation method according to claim 14, wherein
in response to the first reference voltage reaching the second reference voltage, comparing the second reference voltage and the feedback voltage by the comparator;
in response to the feedback voltage being less than the second reference voltage, turning on the switch by the comparator; and
in response to the feedback voltage being greater than the second reference voltage, turning off the switch by the comparator.

17. An application circuit, comprising:
a plurality of charge pump devices, wherein input terminals of the charge pump devices receive a same power supply voltage, the charge pump devices execute a pumping operation on the power supply voltage based on triggering of a clock signal to generate a plurality of output voltages with different slew rates.

18. The application circuit according to claim 17, wherein each of the charge pump devices comprises:
a switch, having a first terminal receiving the clock signal;
a charge pump circuit, having a clock terminal coupled to a second terminal of the switch, wherein an input terminal of the charge pump circuit receives the power supply voltage, and in response to the switch being turned on, the charge pump circuit executes the pumping operation on the power supply voltage based on the clock signal of the clock terminal to generate the output voltage;
a slew rate control circuit, generating a first reference voltage with a slew rate; and
a comparison circuit, coupled to the slew rate control circuit to receive the first reference voltage, coupled to an output terminal of the charge pump circuit to receive the output voltage, and coupled to a control terminal of the switch, wherein the comparison circuit checks the first reference voltage and a second reference voltage with a fixed level, wherein
in response to the first reference voltage not reaching the second reference voltage, the comparison circuit determines whether to turn on the switch based on a first level relationship between the first reference voltage and the output voltage;
in response to the first reference voltage reaching the second reference voltage, the comparison circuit determines whether to turn on the switch based on a second level relationship between the second reference voltage and the output voltage.

19. The application circuit according to claim 18, wherein the slew rate control circuit comprises:
a current mirror, having a main current path and a slave current path, wherein a first terminal of the main current path and a first terminal of the slave current path receive the power supply voltage;
a current source, coupled to a second terminal of the main current path; and
a capacitor, coupled to a second terminal of the slave current path,
wherein the second terminal of the slave current path generates the first reference voltage with the slew rate to the comparison circuit in a power-on stage of the power supply voltage.

20. The application circuit according to claim 18, wherein the comparison circuit comprises:
a feedback circuit, having an input terminal coupled to the output terminal of the charge pump circuit to receive the output voltage, wherein the feedback circuit generates a feedback voltage based on the output voltage; and
a comparator, determining whether to turn on the switch based on the first reference voltage, the second reference voltage and the feedback voltage, wherein a first non-inverting input terminal of the comparator is coupled to the slew rate control circuit to receive the first reference voltage, a second non-inverting input terminal of the comparator receives the second reference voltage, an inverting input terminal of the comparator is coupled to an output terminal of the feedback circuit to receive the feedback voltage, and an output terminal of the comparator is coupled to the control terminal of the switch.
